(19) United States
(12) Patent Application Publication
(10) Pub. No.: US 2025/0350096 A1
(43) Pub. Date: Nov. 13, 2025

(54) DEVICES INCLUDING IIIxOz , AlyOz SUPERLATTICES

(71) Applicant: CORNELL UNIVERSITY, Ithaca, NY (US)

(72) Inventors: Yifan ZHANG, Ithaca, NY (US); Guru Bahadur Singh KHALSA, Ithaca, NY (US); Debdeep JENA, Ithaca, NY (US); Hari NAIR, Ithaca, NY (US); Vladimir PROTASENKO, Ithaca, NY (US)

(73) Assignee: CORNELL UNIVERSITY, Ithaca, NY (US)

(21) Appl. No.: 18/862,435

(22) PCT Filed: Apr. 26, 2023
(86) PCT No.: PCT/US2023/019910

§ 371 Date: Nov. 1, 2024

Related U.S. Application Data
(60) Provisional application No. 63/337,224, filed on May 2, 2022.

(51) Int. Cl. H01S 5/34; H01S 5/024; H01S 5/026; H01S 5/14; H10D 30/00; H10D 30/47; H10D 62/10; H10F 30/21; H10F 30/221; H10F 77/14

(52) U.S. Cl. CPC H01S 5/3401; H01S 5/026; H01S 5/14; H01S 5/3407; H10D 30/47; H10D 30/502; H10F 30/221; H10F 30/288; H10F 77/146; H01S 5/02415; H10D 62/121

(57) ABSTRACT

A device including a base structure, and a superlattice structure, the superlattice structure disposed on the base structure. The superlattice structure includes a number of (IIIx, Aly)Oz layers, III being a Group 3 element different from Aluminum; where a composition (x, y) and thickness of each layer is selected to provide a preselected energy band structure.

### CROSS-REFERENCE TO RELATED APPLICATIONS

This application claims priority to U.S. Provisional Patent Application No. 63/337,224, entitled DEVICES INCLUDING (IIIx, Aly)Oz SUPERLATTICES, filed May 2, 2022, which is incorporated herein by reference in its entirety and for all purposes.

### STATEMENT REGARDING FEDERALLY SPONSORED RESEARCH OR DEVELOPMENT

This invention was made with U.S. Government support from the National Science Foundation (Platform for the Accelerated Realization, Analysis and Discovery of Interface Materials (PARADIM)) under Cooperative Agreement No. DMR-1539918. The U.S. Government has certain rights in the invention.

### BACKGROUND

This invention relates generally to devices including (IIIx, Aly)Oz superlattices.

The recent integration of Ga₂O₃ with Al₂O₃ has the potential to revolutionize high-power electronics. The availability of large, inexpensive, single-crystal substrates 1, recent advances in thin film growth, and the ability to dope these wide-bandgap semiconductors have enabled transistors and Schottky diodes based on Ga₂O₃ with breakdown fields as large as 5.45 MV/cm and 5.7 MV/cm and approaching the projected theoretical estimate of 8 MV/cm. Comparing these breakdown fields with the existing technological semiconductors Si (0.3 MV/cm), SiC (3.1 MV/cm), and GaN (3.3 MV/cm), β-Ga₂O₃ promises new high-frequency, high-voltage, and high-temperature electronics applications. α-Ga₂O₃ and a-Al₂O₃ further expand the bandgap to 5.2 eV and 8.8 eV, signifying the potential for oxide semiconductors to expand the future electronics and pho-tonics materials tool-set.

Superlattices have been used for field-effect transistors, lasers, and detectors. However, the previous designs for lasers used in superlattices do not provide designs for lasers at the telecommunication frequencies. The previous designs for detectors used in superlattices do not include designs for detectors that can sense in two different separate wavelength ranges (two-tone detectors) where the wavelengths are in the IR and in the UV.

There is a need for lasers that have higher optical power than conventional mid and far infrared lasers and that can operate at the telecommunication frequencies and for detectors that can sense in two different separate wavelength ranges.

### BRIEF SUMMARY

Lasers that can operate at the telecommunication frequencies and for detectors that can sense in two different separate wavelength ranges and that can sense in two different separate wavelength ranges are presented herein below.

In one or more instantiations, the device of these teachings includes a base structure, and a superlattice structure, disposed on the base structure. The superlattice structure includes a number of (IIIx, Aly)Oz layers, III being a Group 3 element different from Aluminum; where a composition (x, y) and thickness of each layer is selected to provide a preselected energy band structure.

A number of other instantiations are presented.

For a better understanding of the present teachings, together with other and further objects thereof, reference is made to the accompanying drawings and detailed description and its scope will be pointed out in the appended claims.

### BRIEF DESCRIPTION OF THE DRAWINGS

FIG. 1 is one instantiation of a superlattice structure of these teachings;

FIG. 2 is another instantiation of the superlattice structure of these teachings;

FIG. 3 shows a further instantiation of the superlattice structure of these teachings;

FIG. 4 shows calculation results for inter-sub and energy for one instantiation of the superlattice structure of these teachings;

FIG. 4A shows the X-ray diffraction (XRD) data of a superlattice of these teachings;

FIG. 4B shows the transmission electron microscopy (TEM) image of an earlier grown superlattice in the β-phase;

FIG. 4C shows the TEM (transmission electron microscopy) images of MBE previously grown layers of α-(Al₁₋ₓGaₓ)₂O₃ on m-plane α-Al₂O₃;

FIG. 4D shows the measured bandgap of the alloy of FIG. 4B;

FIG. 5 shows a quantum cascade laser structure using superlattice structures of these teachings;

FIG. 6 shows a typical laser design of a superlattices based quantum cascade laser;

FIG. 7 shows a typical laser design using GaN/AlN layers;

FIG. 7A shows an instantiation in which a frequency comb is obtained from the oxide superlattices of these teachings;

FIG. 8 shows a quantum cascade laser using one superlattice structure of these teachings and combined with a heat transfer component;

FIG. 9 shows a two-tone detector using another superlattice structure of these teachings;

FIG. 10 shows another instantiation of a two-tone detector using another superlattice structure of these teachings;

FIGS. 11A-11D depict Crystal structure of monoclinic β-Ga₂O₃, and rhombohedral α-Ga₂O₃ and α-Al₂O₃;

FIGS. 12A-12K show electronic structure of β-Ga₂O₃, α-Ga₂O₃, and α-Al₂O₃; FIGS. 12A, 12B show the first Brillouin zone of the monoclinic β and rhombohedral α phases; FIGS. 12C, 12F, 12I show the DFT band structure and orbital-projected DOS of β-Ga₂O₃, α-Ga₂O₃, and α-Al₂O₃; FIGS. 12D, 12G, 12J show the tight-binding band structure and DOS plotted over the DFT data; FIGS. 12E, 12H, 12K show DFT) and tight-binding band structure near the Γ point; and

FIGS. 13A-13F show crystal and electronic structure of α-Ga₂O₃/α-Al₂O₃ superlattices along the direction; FIG. 13A shows the superlattice is constructed by interfacing conventional (hexagonal) cells of Ga₂O₃3 and Al₂O₃ along the direction; FIG. 13B shows Flat band diagram of the superlattice quantum confinement of fixed Ga₂O₃ for varied Al₂O₃ thickness (upper) and varied Ga₂O₃ and Al₂O₃ thickness (lower); FIG. 13C shows superlattice hand structure from the tight-binding model for one conventional cell of Ga₂O₃ and one conventional cell of Al₂O₃; FIG. 13D shows transition energy from the valence band edge to the conduction sub-bands from the tight-binding model for fixed Ga₂O₃ thickness (upper panel of FIG. 13B; FIG. 13E shows eigenvectors of the lowest three conduction sub-bands projected onto the metal sites showing the expected even (bottom), odd (middle), even (top) parity in the confined Ga₂O region (shaded green); FIG. 13F shows transition energy from the valence band edge to the conduction sub-bands from the tight-binding model for varied Ga₂O₃ thickness (lower panel of FIG. 13B);

FIG. 14A shows an instantiation in which results in a multichannel transistor with a superlattice is etched into a fin structure; and

FIG. 14B shows another instantiation including multiple fins in parallel.

### DETAILED DESCRIPTION

The following detailed description presents the currently contemplated modes of carrying out the invention. The description is not to be taken in a limiting sense but is made merely for the purpose of illustrating the general principles of the invention, since the scope of the invention is best defined by the claims.

As used in the specification and claims, for the purposes of describing and defining the disclosure, the terms about and substantially are used to represent the inherent degree of uncertainty that may be attributed to any quantitative comparison, value, measurement, or other representation. The terms about and substantially are also used herein to represent the degree by which a quantitative representation may vary from a stated reference without resulting in a change in the basic function of the subject matter at issue. Comprise, include, and/or plural forms of each are open ended and include the listed parts and can include additional parts that are not listed and/or is open-ended and includes one or more of the listed parts and combinations of the listed parts

For clearer understanding of these teachings, the following definitions are provided.

“Group III” (or “III”), as used here in, refers to a group of elements in the periodic table including what are now called Group 13 elements: boron (B), aluminum (Al), gallium (Ga), indium (In), thallium (TI).

“III,” as used herein, refers to one of the elements or a combination of elements from group III. Of the Group III elements, one skilled in the art would know that boron trioxide is not a semiconductor (Boron trioxide s almost always found as the vitreous (amorphous) form; however, it can be crystallized after extensive annealing (that is, under prolonged heat). See www.chemeurope.com/en/encyclopedia/Boron_trioxide.html).) One skilled in the art would also know that thallium trioxide can be a degenerate (very highly doped) semiconductor (see, Richard J. Phillips et al., Electrochemical and photoelectrochemical deposition of thallium (III) oxide thin films, Journal of Materials Research 4, 923-929 (1989) and H. P. Geserich, Phys. Status Solidi 25, 741 (1968)) and is unlikely to be used in a transistor. One skilled in the art would know that Nihonium (the element formerly known as ununtrium) has not been seen as having any oxides since the most stable isotope of Nihonium (Nihonium-286) has a half-life of around 8 seconds and decays into Roentgenium, which is also unstable and part of the copper group (See periodic-table.com/nihonium/).)

A “two-tone” detector, as used herein, refers to a detector of electromagnetic radiation that detects radiation in two frequency ranges, for example, the IR range and the UV range.

“Superlattice,” as used herein, is a structure of layers of two (or more) materials.

An “optical frequency comb,” as used herein, refers to coherent radiation generated by an optical source, whose spectrum has a set of modes perfectly equally spaced, and whose modes have a well-defined phase relationship between each other.

In one or more instantiations, the device of these teachings includes a base structure, and a superlattice structure, disposed on the base structure. The superlattice structure includes a number of (IIIx, Aly)Oz layers, III being a Group 3 element different from Aluminum; where a composition (x, y) and thickness of each layer is selected to provide a preselected energy band structure. In order to further elucidate these teachings, one instantiation, where (IIIx, Aly)Oz is (Gax, Aly)Oz is presented herein below. It should be noted that these teachings are not restricted to only this instantiation.

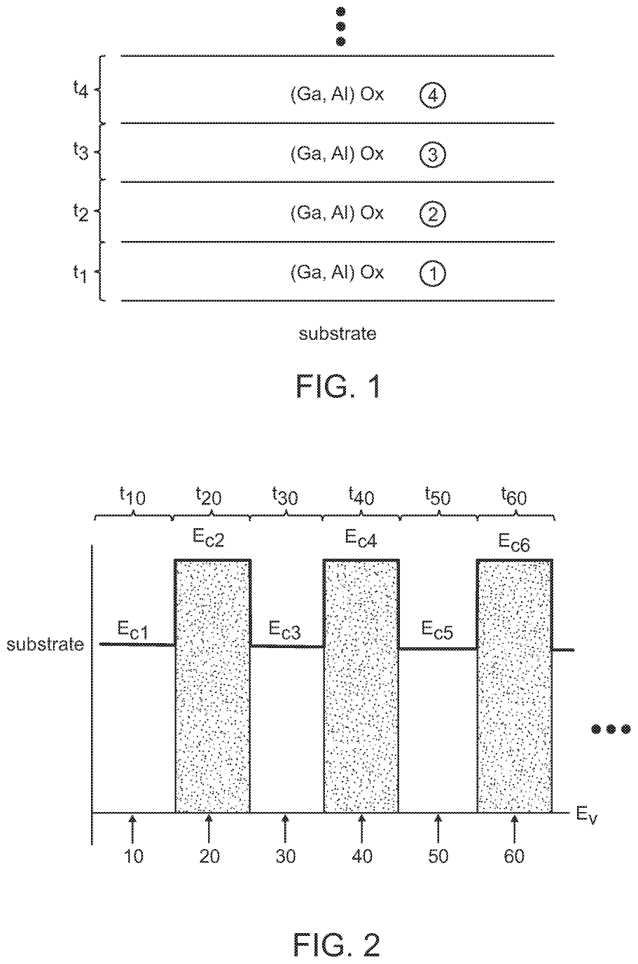

FIG. 1 shows one instantiation of a superlattice structure of these teachings. Referring to FIG. 1, FIG. 1 shows (Gax, Aly)Oz (labeled as GaAlOx) superlattice consists of alternative layers 1, 2, 3, 4 (with thicknesses t₁, t₂, t₃ and t₄) of (Gax, Aly)Oz alloy on a substrate. The possible substrates materials and the corresponding crystal orientations include α-Ga₂O₃, α-Al₂O₃, SiC, GaN, AlN: c-/a-/r-/m-plane, α-Ga₂O₃, α-Al₂O₃, SiC, GaN, AlN: c-/a-/r-/m-plane, β-Ga₂O₃: [-201]/plane, Si: plane, SiC: 4H and 6H.

In FIG. 2, white layers 10, 30, 50 have higher Ga percentage and grey layers 20, 40, 60 have higher Al percentage. With higher Al percentage, conduction band electrons need more energy to stay in the grey layers 20, 40, 60 (E_{c2}, E_{c4}, E_{c6}) than staying in the white layers 10, 30, 50 (E_{c1}, E_{c3}, E_{c5}), so the grey layers 20, 40, 60 act as a barrier layer for conduction band electrons. The figure shows how the grey layers 20, 40, 60 act as a barrier and confine electrons in the white layers 10, 30, 50.

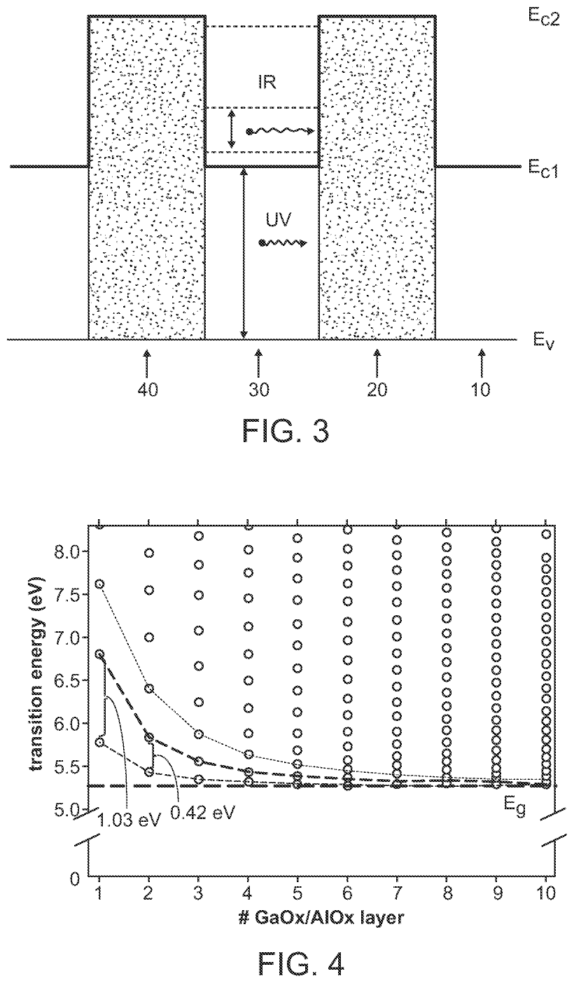

As shown in FIG. 3, by tuning the composition of individual layers (effectively changing the height of E_{c}) and their thickness, the properties of the superlattices for different functionalities are selected (engineered). The figure above demonstrates the formation of miniband energy levels, shown as the dashed line, which is engineered by varying the composition of individual layers and the thickness of individual layers. The transition between the minibands is thus be engineered to span an energy range as high as over 1 eV, which covers the optical telecommunication wavelength of 1.55 μm. This sufficiently covers the majority of the infrared band (IR) region of the electromagnetic spectrum. The transition of electrons from the valence band (Eᵥ) to the miniband requires photons of energies above ˜5 eV which is in the ultraviolet frequency (UV).

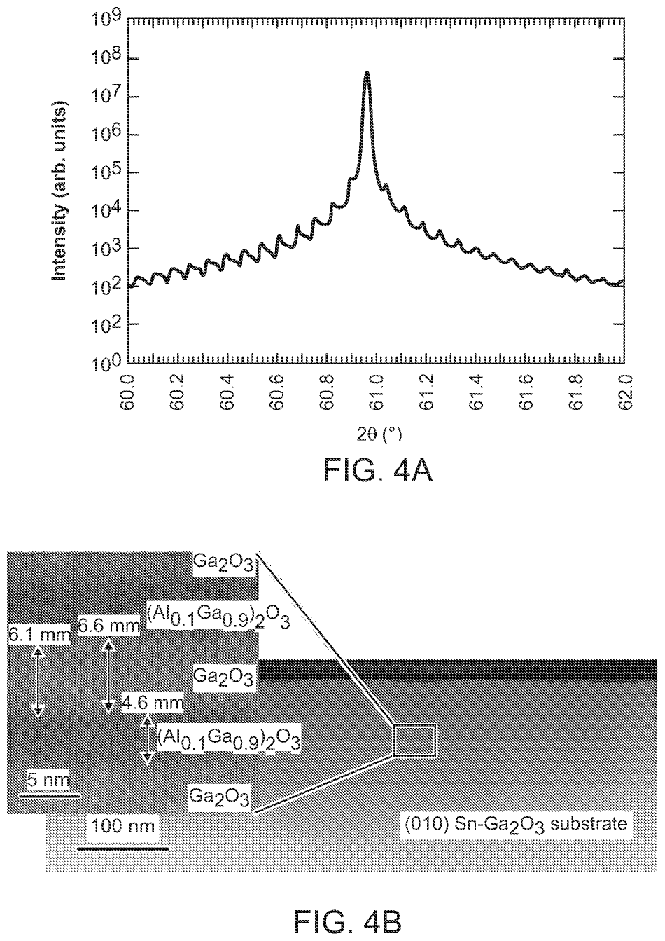

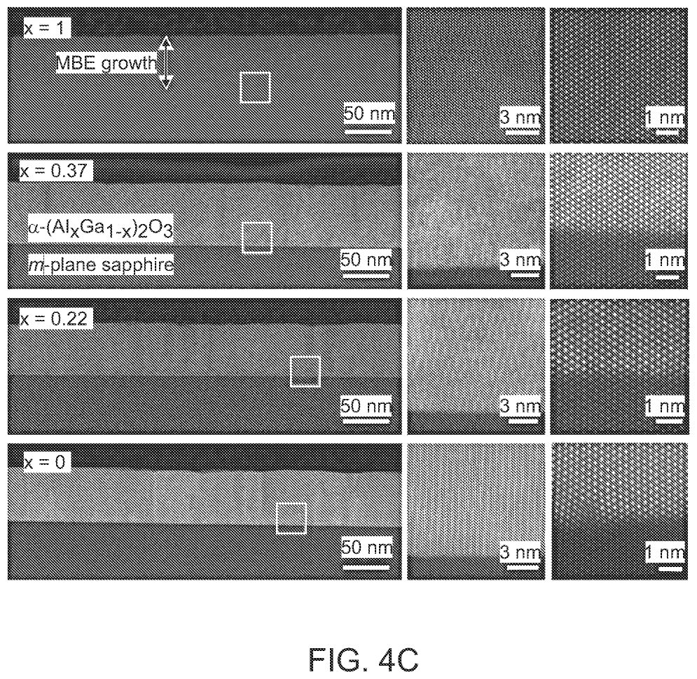

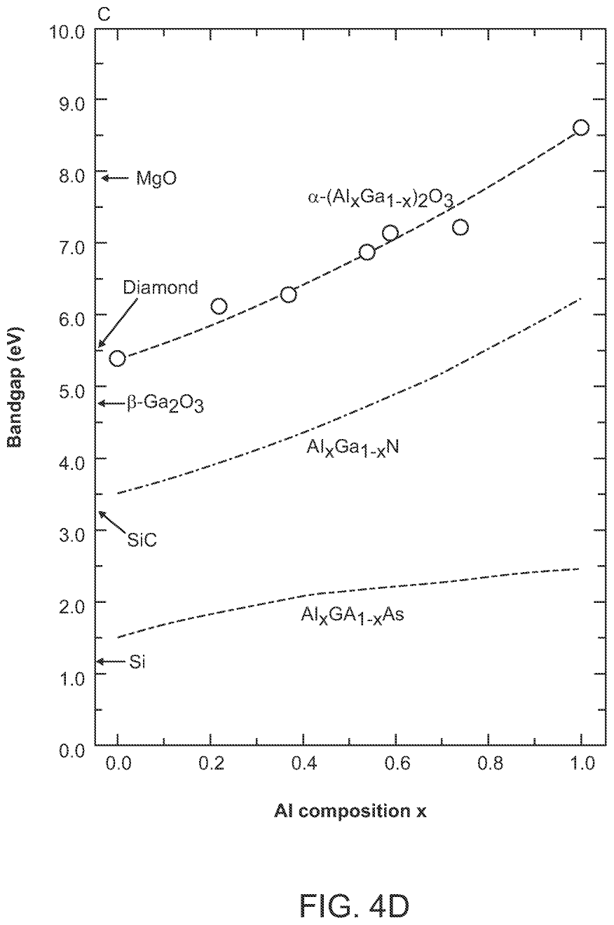

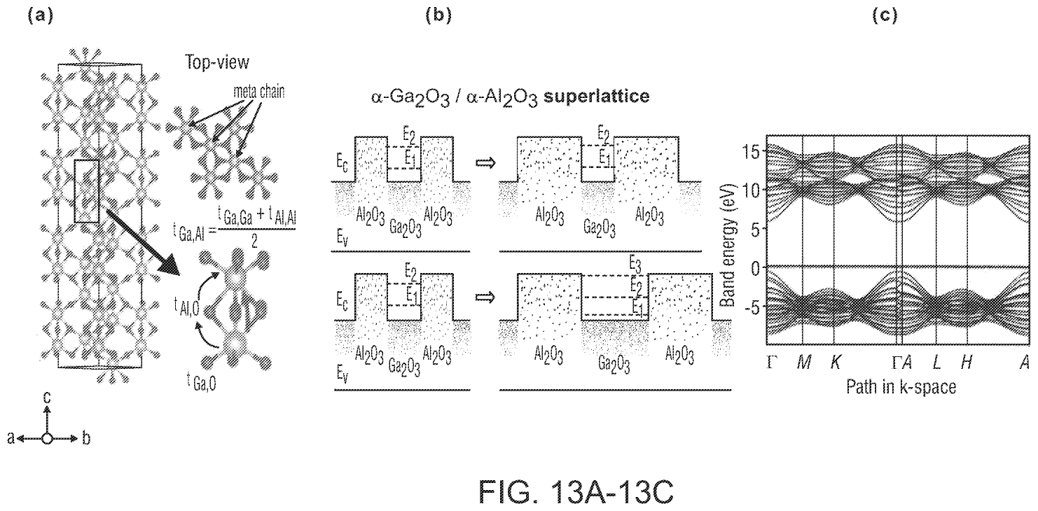

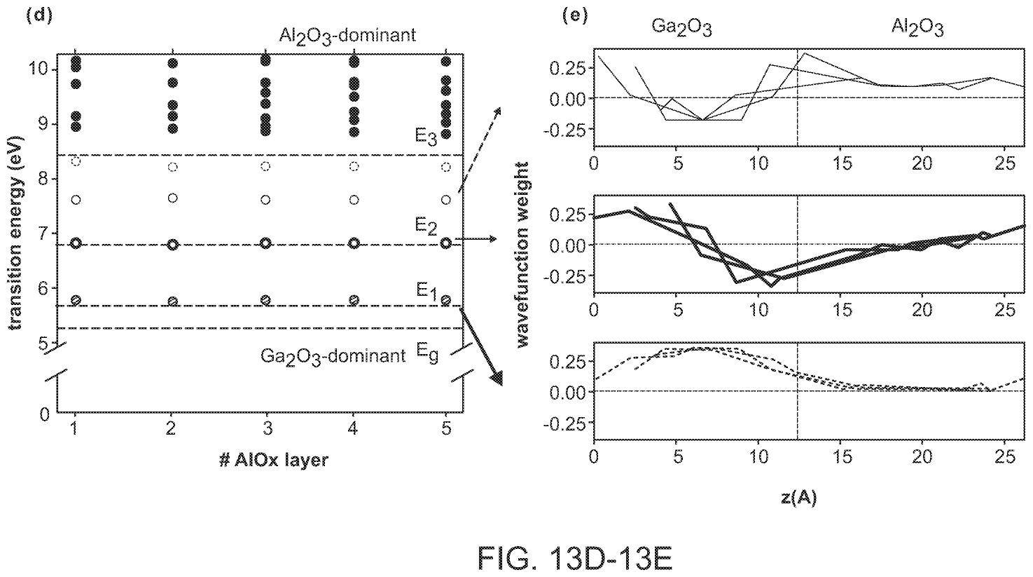

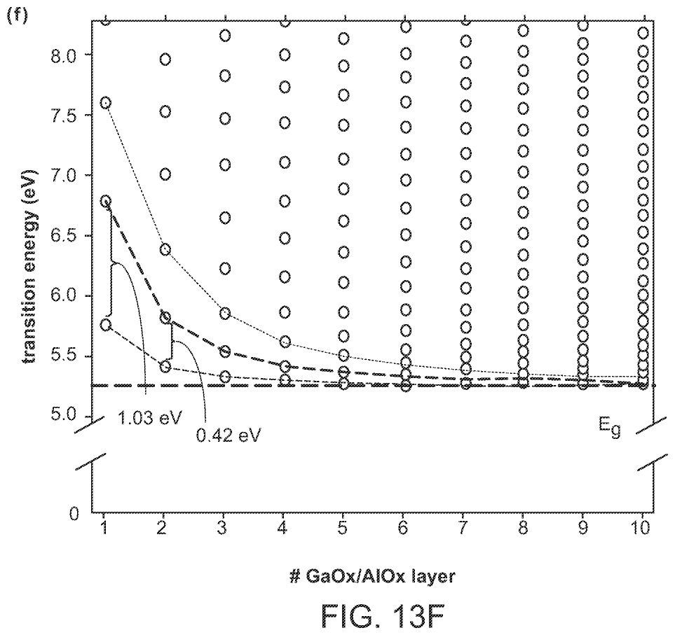

FIG. 4, excerpted from the FIG. 13F, presents the tight-binding calculation result of the inter-sub-band transition energy. The inter-sub-band transition reaches 1.03 eV at one unit cell of GaOx quantum well thickness.

The tuning disclosed above also allows for the design of coupling between adjacent wells for each miniband level, which affects the transport properties of electrons injected or photogenerated and plays an important role in designing lasers and detectors.

FIG. 4A shows the X-ray diffraction (XRD) data of a multilayer structure (superlattice) of repeating Ga₂O₃/Al0.2Ga1.803 in the β-phase, grown by metal-organic chemical vapor deposition (MOCVD). The observation of multiple of fringes indicate a good quality of the multilayer structure.

FIG. 4B shows the transmission electron microscopy (TEM) image of an earlier grown Ga₂O₃/Al0.2Ga1.8O3 superlattice in the β-phase (see Cheng, Z. et al. Significantly reduced thermal conductivity in β-(Al0.1Ga0.9)2O3/Ga2O3 superlattices. Appl Phys Lett 115, 092105 (2019, which is incorporated by reference herein in its entirety and for all purposes). The image presents high-quality periodic repetitions between the two compositions.

In earlier work, the MBE growth of α-(Al₁₋ₓGaₓ)₂O₃ on m-plane α-Al₂O₃ with arbitrary x was demonstrated (see Jinno, R. et al. Crystal orientation dictated epitaxy of ultrawide-bandgap 5.4- to 8.6-e V α-(AlGa)2O3 on m-plane sapphire. Sci Adv 7, eabd5891 (2021), which is incorporated by reference herein in its entirety and for all purposes). The TEM shown in FIG. 4C demonstrates the stabilization of the heterostructure up to some large thickness of around 50 nm. FIG. 4D shows the measured bandgap of the alloy, spanning a window between 5.4 eV and 8.6 eV. These values are consistent with the model discussed hereinbelow.

A Quantum Cascade Laser (QCL) has a periodic series of thin layers of varying material composition forming a superlattice. The superlattice introduces a varying electric potential across the length of the device, meaning that there is a varying probability of electrons occupying different positions over the length of the device. This is referred to as one-dimensional multiple quantum well confinement and leads to the splitting of the band of permitted energies into a number of discrete electronic subbands. By suitable design of the layer thicknesses it is possible to engineer a population inversion between two subbands in the system which is required in order to achieve laser emission. Because the position of the energy levels in the system is primarily determined by the layer thicknesses and not the material, it is possible to tune the emission wavelength of QCLs over a wide range in the same material system. (see en.wikipedia.org/wiki/Quantum-cascade laser). The energy diagram for a QCL can be seen in. for example, S. Slivken, V. I. Litvinov. M. Razeghi, and J. R. Meyer, Relaxation kinetics in quantum cascade lasers, Journal of Applied Physics 85, 665 (1999), which is incorporated by reference herein in its entirety and for all purposes.

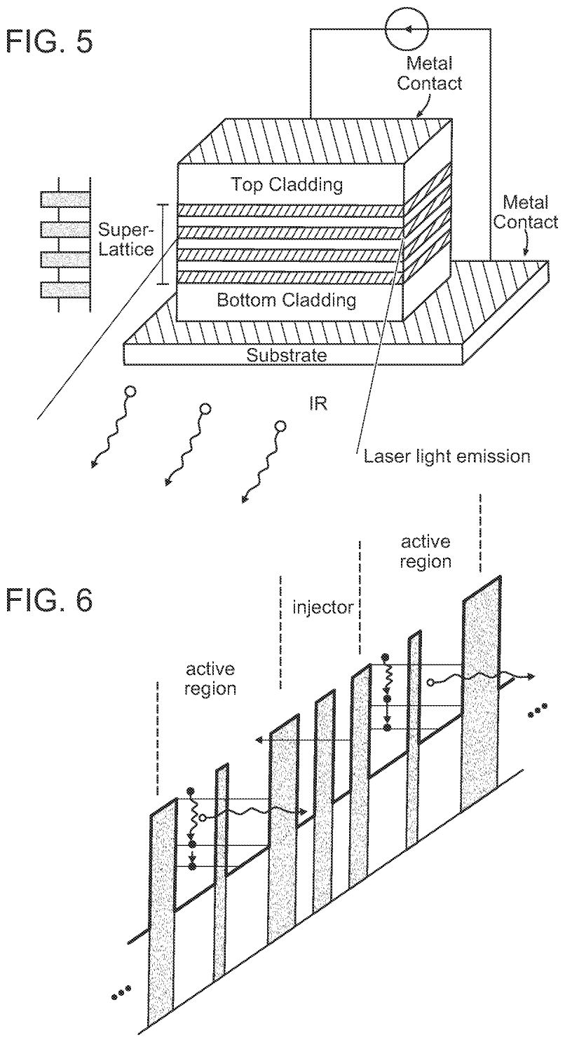

FIG. 5 shows a quantum cascade laser structure using superlattice structures of these teachings. (Quantum cascade lasers are described, for example, in U.S. Pat. Nos. 5,936,989, 6,091,753, and 8,014,430 and in Jerome Faist, Federico Capasso, Deborah L. Sivco, Carlo Sirtori, Albert L. Hutchinson, Alfred Y. Cho, Quantum Cascade Laser, Science, Vol. 264, 22 Apr. 1994, pp. 563-556, all of which are incorporated by reference herein in their entirety and for all purposes.) Referring to FIG. 5, a superlattice of these teachings is used to realize a quantum cascade laser (QCL) that emits photons at telecommunication wavelengths. The central part of the QCL is the superlattice shown therein. The superlattice is sandwiched by a base structure (referred to as top cladding layer) and a bottom structure (referred to as a bottom cladding layer). These two structures serve two functions: they inject carriers into the superlattice, and together they serve as a resonator to select a specific frequency. The top and bottom claddings are covered with metal electrodes to connect to external current source. At sufficient current injection, the QCL emits laser light in the IR and/or telecommunication wavelengths from the edge. The QCL of these teachings can emit electromagnetic radiation a wavelength between 400 nm and 10.0 μm (which includes between 400 nm and 600 nm, in the visible range, between 1.26 μm and 1.75 μm, the optical communication wavelengths, or between 1.00 μm and 2.00 μm),

FIG. 6 presents a typical layer design of a QCL and demonstrates its working principle. It consists of alternating active regions and injectors. Active regions are where stimulated emission occurs, and injector layers inject electrons from the bottom level of the previous active region to the top of the next active region. The active region is typically engineered (through varying the parameters discussed hereinabove to contain 3 energy levels. The highest level receives electrons from the injector and transition to the second highest level to emit a photon in the IR frequency. After radiation, the electron quickly relaxes to the lowest level through phonon relaxation. This is achieved through engineering the level spacing such that the transition energy between the second highest level and the lowest level is resonant with an optical phonon frequency. Once the electron relaxes transition to the lowest level, it will tunnel through the injector and enter the top level of the next active region.

A typical application of semiconductor laser is to convert electric signal to light propagating in the optical fiber, achieving an interface between electrical and optical communications. In this scenario, QCL brings a unique advantage in terms of fast optics: it can be modulated at a frequency much higher than conventional lasers because of the fast phonon relaxation process, which allows for higher data transmission rate. With the above demonstration of QCL in the telecommunication wavelength, it significantly expands the data capacity of optical communication networks.

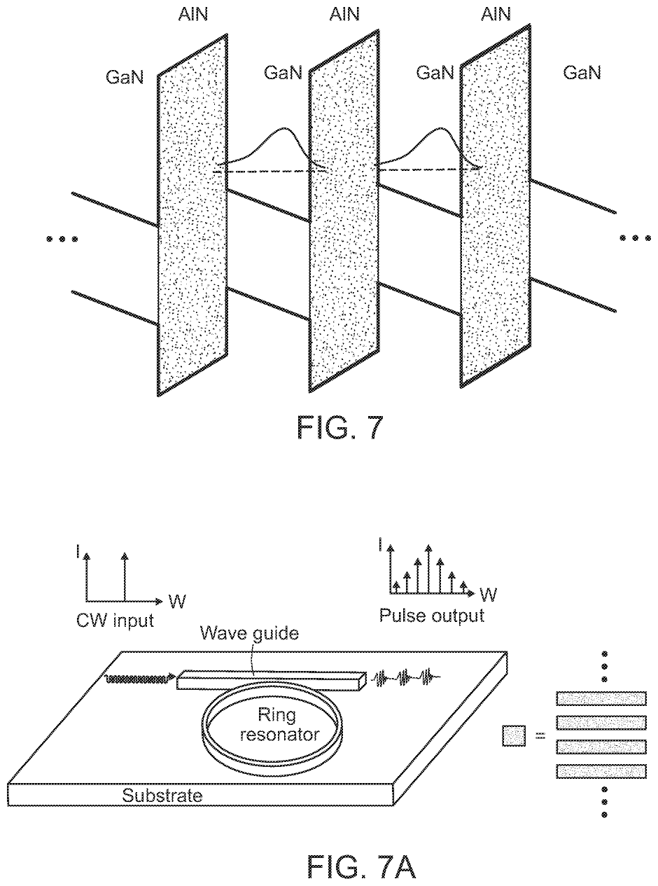

QCL emitting at the telecommunication wavelength can in principle be achieved with alternative material systems. For example, as shown in FIG. 7, GaN/AlN material system can also form superlattice and provide enough bandgap offset to allow for inter-sub-band transition at the telecommunication wavelength. However, GaN and AlN lack central inversion symmetry, creating tilted quantum wells and trap electrons to one side (shown in FIG. 7). This phenomenon impairs the ability of electrons to tunnel through the quantum wells, a necessary process to achieve lasing condition. On the other hand, the GaOx/AlOx material system preserves central inversion symmetry and does not have this problem.

Another application of QCL is to utilize the third-order non-linearity within the device to create s. QCL optical frequency combs as shown in Jerome Faist, Gustavo Villares, Giacomo Scalar, Markus Misch, Christopher Bonzon, Andreas Hugi, and Mattias Beck, Quantum Cascade Laser Frequency Combs, Nanophotonics 2016; 5 (2):272-291, which is incorporated by reference herein in its entirety and for all purposes. Optical Frequency combs allow for precise time metrology. [0001] FIG. 7A shows an instantiation in which a frequency comb is obtained from the oxide superlattices of these teachings. The superlattice is patterned into a ring resonator and coupled to a waveguide. (see, for example, Michael Stefszky et al., Towards optical-frequency-comb generation in continuous-wave-pumped titanium-in diffused lithium-niobate waveguide resonators, Phys. Rev. A 98, 053850, 2018, A. Yariv, Critical coupling and its control in optical waveguide-ring resonator systems, IEEE Photonics Technology Letters, Volume: 14, Issue: 4, pp. 483-485, April 2002, and U.S. Patent Application Publication, No. 2008/0285606A entitled METHOD AND APPARATUS FOR OPTICAL FREQUENCY COMB GENERATION USING A MONOLITHC MICRO-RESONATOR, published November 20, 2008, all of which are incorporated by reference herein in their entirety and for all purposes). Continuous-wave (CW) laser is sent into the waveguide and then builds up in the ring resonator. The large optical nonlinearity in the superlattice converts the monotone laser into evenly spaced frequencies and sends out from the waveguide, in time domain, the output is pulsed with the frequency equal to the frequency spacing in the frequency domain, (the optical nonlinearities needed to obtain the frequency comb are related to the band structure ss can be see, for example, in M. J. Shaw et al., Role of the band structure in determining the third-order susceptibility of semiconductor superlattices, Phys. Rev. B, Vol. 45, Issue 19, pp. 11031-11035, 1991, in W. R. L. Lambrecht, S. N. Rashkeev, From Band Structures to Linear and Nonlinear Optical Spectra in Semiconductors, Physica Status Solidi, Volume 217, Issue 1, Pages 599-640, 2000, all of which are incorporated by reference herein in their entirety and for all purposes.) These features make the frequency comb attractive for various metrological applications.

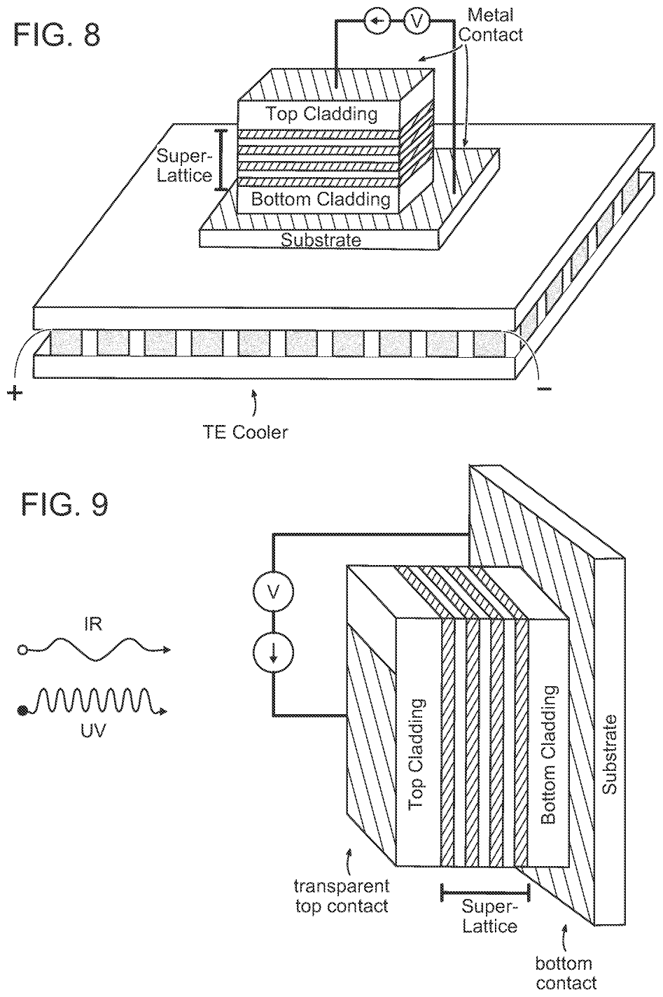

As shown in FIG. 8, QCL is often combined with a cooler, such as a thermoelectric (TE) cooler, to operate at −100 K.

This superlattice structure can also serve as a two-tone detector which detects both IR and UV light. Photodetection in semiconductors works starts with the creation of electron-hole pairs by photons. For a given bandgap and a given photon energy, the absorbed photons promote electrons from the valence band into the conduction band. For a preselected energy band structure, the promoting of electrons to the conduction band can happen at two different electromagnetic radiation ranges,

FIG. 9 shows the schematics of the two-tone detector which receives light from above. On the instantiation shown in FIG. 9, a top electrically conducting contact is disposed over at least a portion of the top structure (also referred to as top cladding) and a bottom electrically conducting contact is disposed over at least a portion of the substrate (also referred to as the bottom structure). In some instantiations, at least one of the top electrically conducting contact or the top cladding layer is substantially transparent, at least in the frequency ranges of interest. In other instances, at least one of the bottom electrically conducting contact or the substrate is substantially transparent, at least in the frequency ranges of interest. An external voltage bias is applied, and the current is monitored to detect the presence of IR/UV light.

For the two-tone detector, the cladding layer need not act as a resonator but still provide carriers into the superlattices. Embodiments in which the current flow is not between the upper cladding (also referred to as an upper structure) and the lower cladding (also referred to as a lower structure) are also within the scope of these teachings (see, for example, Martin Walther et al., InAs/GaSb type II superlattices for advanced 2nd and 3rd generation detectors, in Quantum Sensing and Nanophotonic Devices VII, edited by Manijeh Razeghi, Rengarajan Sudharsanan, Gail J. Brown, Proc. of SPIE Vol. 7608, 2010 and in A. D. D. Dwivedi et al., Numerical Simulation of HgCdTe Based Simultaneous MWIR/LWIR Photodetector for Free Space Optical Communication, International Journal of Advanced Applied Physics Research, 2015, Vol. 2, No. 1, pp. 37-45, both of which is incorporated are reference herein in their entirety and for all purposes).

While UV detector based on GaOx has been widely investigated, there has been no proposal for devices that are both UV and IR active based on the oxide material system,

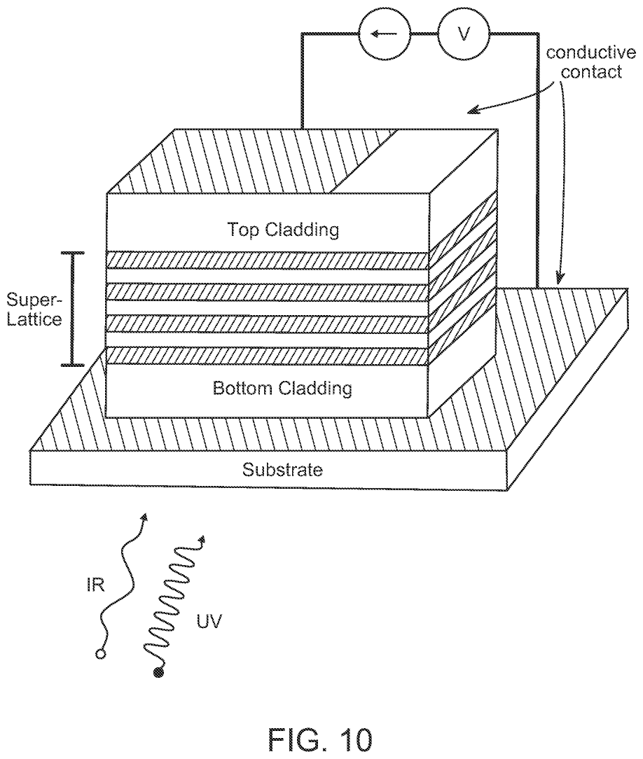

Another design of the two-tone detector, shown in FIG. 10, receives the light on the edge. This does not require a transparent top cladding, but the area of the edge is usually much smaller than the top surface, so the flux density of the IR/UV photon captured will be lower.

The lower capture efficiency can be overcome by integrating the device into an engineered dielectric media which allows for the broad propagating mode to couple to the narrow surface mode to be detected by the two-tone detector. This integration in principle can enhance the capture efficiency significantly. This idea has been demonstrated to enhance the single-photon emission efficiency of the NV center (See Srivatsa Chakravarthi, Pengning Chao, Christian Pederson, Sean Molesky, Andrew Ivanov, Karine Hestroffer, Fariba Hatami, Alejandro W. Rodriguez, and Kai-Mei C. Fu, Inverse-designed photon extractors for optically addressable defect qubits, Optica, Vol. 7, Issue 12, pp. 1805-1811 (2020), which is incorporated by reference herein in its entirety and for all purposes.)

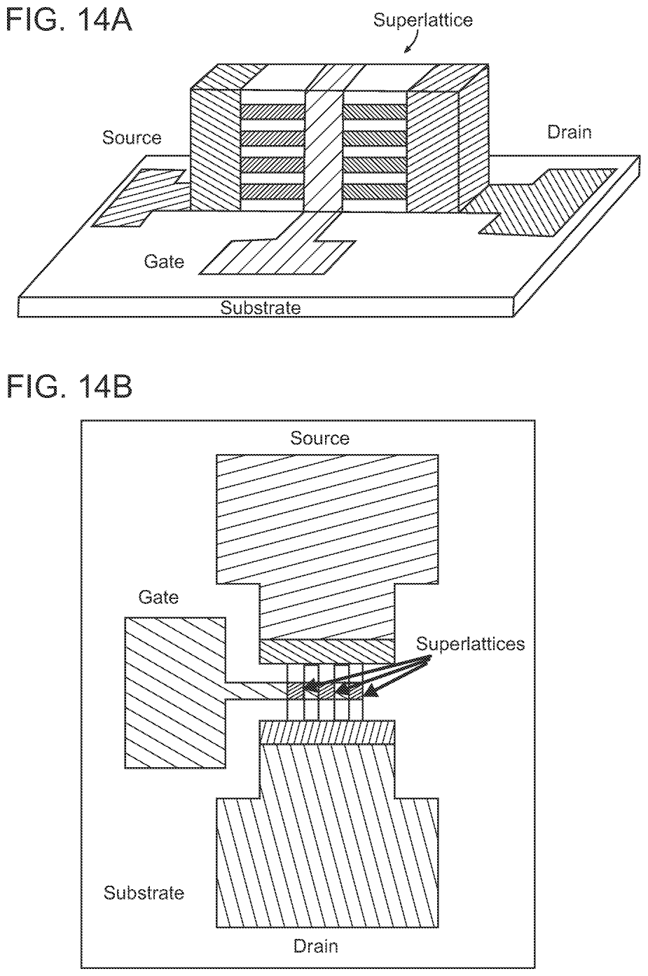

FIG. 14A shows an instantiation which results in a multichannel transistor. Similar to the photonic devices proposed above, this device consists of the similar superlattice structure. However, rather than creating photon emission via intersubband transition, the wells carry electrical current horizontally. In the device structure shown in FIG. 14A, the superlattice is etched into a fin structure. The superlattice fin is connected to a source electrode and a drain electrode on the two ends. In the middle, the channels (quantum wells conducting currents) are electrically controlled by a gate electrode. Conventional transistors consist of only one channel and faces the trade-off between the carrier density and the mobility, both of which are crucial parameters to the transistor's performance. The multichannel transistor circumvents this trade-off by increasing the carrier density with multiple channels so that individual channels still have high mobility. This renders the multichannel transistors advantageous for future electronics.

FIG. 14B shows another instantiation including multiple fins in parallel, each fin being individually gated but sharing the same gate electrode. This further boosts the device current without compromising the gate controllability.

The successful design of the above discussed devices, and future electronic and photonics devices requires accurate modeling and understanding of the electronic structure and bonding of Ga₂O₃ and Al₂O₃. The tight-binding method provides a flexible, chemically motivated description of the electronic structure of materials (See, for example, Fernand Spiegelman, Nathalie Tarrat, Jérôme Cuny, Leo Dontot, Evgeny Posenitskiy, Carles Martí, Aude Simon & Mathias Rapacioli (2020) Density-functional tight-binding: basic concepts and applications to molecules and clusters, Advances in Physics: X, 5:1, 1710252, which is incorporated by reference herein in its entirety and for all purposes). When compared with modern computational approaches to materials physics like density functional theory (DFT), tight-binding models are compact, intuitive, and require less computational resources. As a result, tight-binding models are ubiquitous in device engineering and development and have successfully described electronic transport and optical properties of bulk materials, heterostructures, and devices. To aid in the development of new high-power electronics, semi-empirical tight-binding models are derived herein below for three technologically relevant oxide semiconductors: β-Ga₂O₃, α-Ga₂O₃, and α-Al₂O₃.

While being unaware of a tight-binding model describing these three oxide semiconductors, a recent study reports a tight-binding model of/3-Ga2O3 using atomic orbitals as a basis, with parameters drawn from DFT calculations (see. Lee, S. Ganguli, A. K. Roy, and S. C. Badescu, “Density functional tight binding study of β-Ga₂O₃, Electronic structure, surface energy, and native point defects,” The Journal of Chemical Physics 150, 174706 (2019), in which the authors employ the model to study the surface energy of β-Ga₂O₃ and formation energy of Ga and O vacancy defects). Below, an alternative tight-binding model with the goal of accurate parameterization of the conduction band and fundamental optical gaps of β-Ga₂O₃, α-Ga₂O₃, and α-Al₂O₃ is derived, so that electrical and optical properties can be faithfully simulated.

In one instantiation, tight-binding models are derived using a Wannier functions basis. (The Wannier functions are a complete set of orthogonal functions used in solid-state physics. See, for example, Jonathan Yates, Wannier Functions: ab-initio tight-binding, Cavendish Laboratory, Cambridge University presentation, which is incorporated by reference here in in his entirety and for all purposes.) Wannier functions are a convenient basis for tight-binding models because they are derived from the underlying band structure of the material, are formally orthogonal, can be localized to atomic sites, and preserve the site symmetry and coordination. This approach of DFT-derived tight-binding has been used successfully to describe the electronic structure of broad classes of technologically important materials including silicon, III-V semiconductors, and 2D materials.

A detailed disclosure and results are provided in the Y. Zhang, M. Liu D. Jena, and G. Khalsa, Tight-binding band structure of β- and α-phase Ga₂O₃ and Al₂O₃, Journal of Applied Physics 131, 175702 (2022) and in U.S. Provisional Patent Application No. 63/337,224, entitled DEVICES INCLUDING (IIIx, Aly) Oz SUPERLATTICES, filed May 2, 2022, both of which are incorporated by reference herein in their entirety and for all purposes.

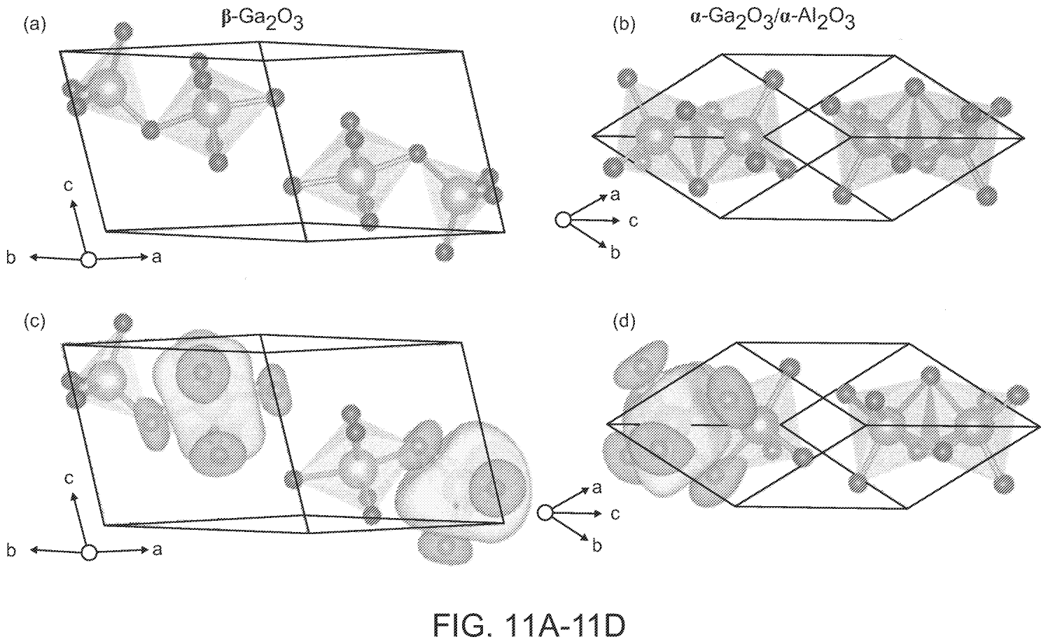

As shown in the Y. Zhang, M. Liu D. Jena, and G. Khalsa, Tight-binding band structure of β- and α-phase Ga₂O₃ and Al₂O₃, Journal of Applied Physics 131, 175702 (2022), FIGS. 11A-11D depict Crystal structure of monoclinic β-Ga₂O₃, and rhombohedral α-Ga₂O₃ and α-Al₂O₃. Coordination octahedra and tetrahedra highlight the different Ga(Al)—O bonding environments in the β (FIG. 11A) and α (FIG. 11B) phases. This bonding difference is evident in the symmetry of Ga(Al)-site Wannier functions (FIG. 11C, 11D) for the conduction band where clear hybridization of the Ga(Al)-s and O-p is seen. In FIGS. 11C, 11D, the positive lobes of the Wannier functions are shown in yellow and the negative lobes are shown in blue.

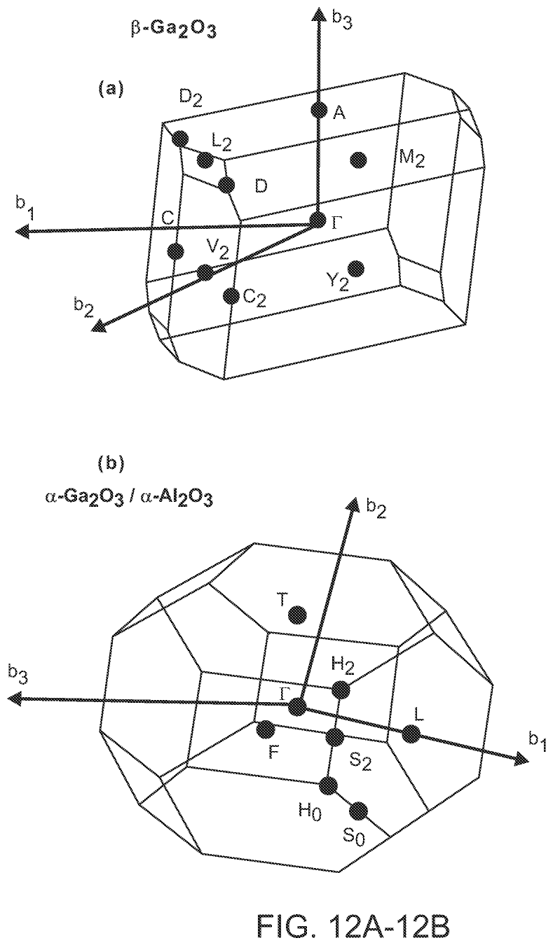

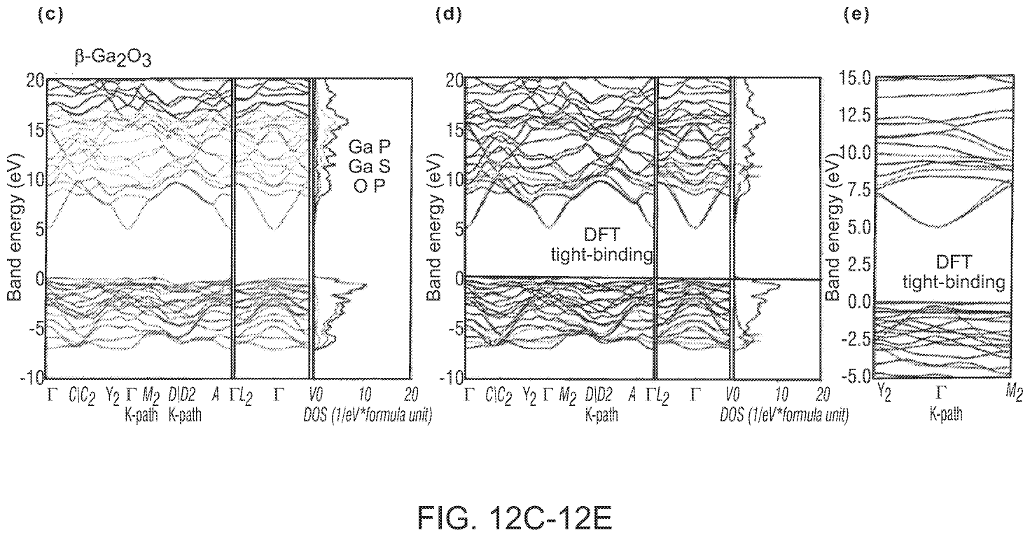

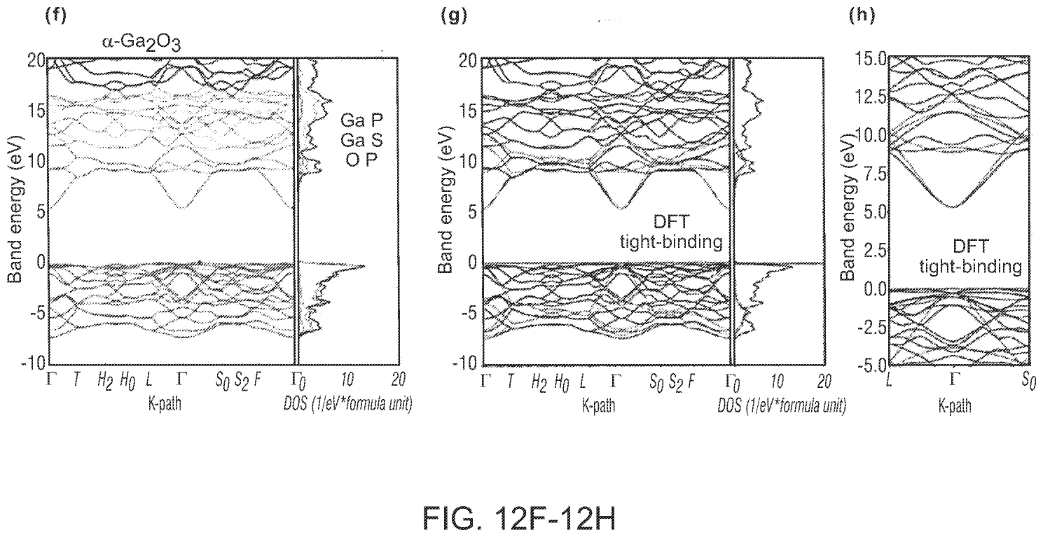

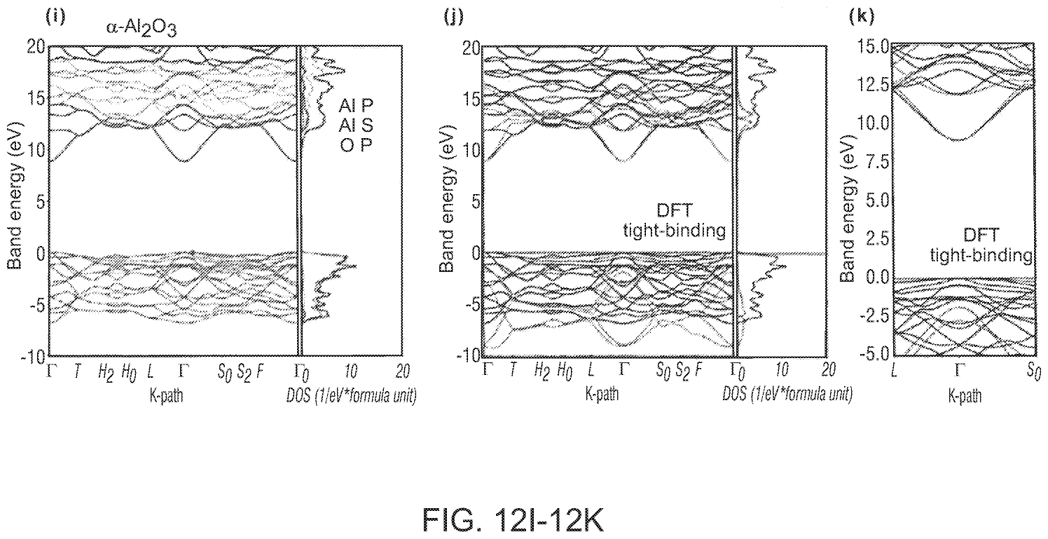

As also shown in Y. Zhang. M. Liu D. Jena, and G. Khalsa, Tight-binding band structure of β- and α-phase Ga₂O₃ and Al₂O₃, Journal of Applied Physics 131, 175702 (2022), FIGS. 12A-12K show electronic structure of β-Ga₂O₃, α-Ga₂O₃, and α-Al₂O₃; FIGS. 12A, 12B show the first Brillouin zone of the monoclinic β and rhombohedral α phases; FIGS. 12C, 12F, 12I show the DFT band structure and orbital-projected DOS of β-Ga₂O₃, α-Ga₂O₃, and α-Al₂O₃. The DFT bandgaps have been tuned to the experimental bandgaps via a scissor cut. Color coordination indicates the orbital character of the bands and projected DOS. The blue dots indicate the valence band maximum. FIGS. 12D, 12G, 12J show the tight-binding band structure and DOS plotted over the DFT data. The sharp peak in the tight-binding DOS at the top of the valence band is due to the lack of O-p to O-p coupling in the tight-binding model. FIGS. 12E, 12H, 12K show DFT) and tight-binding band structure near the Γ point.

As further shown in the Y. Zhang, M. Liu D. Jena, and G. Khalsa. Tight-binding band structure of β- and α-phase Ga₂O₃ and Al₂O₃, Journal of Applied Physics 131, 175702 (2022), FIGS. 13A-13F show crystal and electronic structure of α-Ga₂O₃/α-Al₂O₃ superlattices along the

direction; FIG. 13A shows the superlattice is constructed by interfacing conventional (hexagonal) cells of Ga₂O₃ and Al₂O₃ along the direction. The effective hopping across the interface is shown in the inset. FIG. 13B shows Flat band diagram of the superlattice quantum confinement of fixed Ga₂O₃ for varied Al₂O₃ thickness (upper) and varied Ga₂O₃ and Al₂O₃ thickness (lower); FIG. 13C shows superlattice band structure from the tight-binding model for one conventional cell of Ga₂O₃ and one conventional cell of Al₂O₃; FIG. 13D shows transition energy from the valence band edge to the conduction sub-bands from the tight-binding model for fixed Ga₂O₃ thickness (upper panel of FIG. 13B). The dashed lines are calculated from the finite-well model. FIG. 13E shows eigenvectors of the lowest three conduction sub-bands projected onto the metal sites showing the expected even (bottom), odd (middle), even (top) parity in the confined Ga₂O region (shaded green). The vertical dashed line represents the interface between Ga2O3 (green shaded region—left) and Al2O3 (blue shaded region—right). FIG. 13F shows transition energy from the valence band edge to the conduction sub-bands from the tight-binding model for varied Ga2O3 thickness (lower panel of FIG. 13B). The lowest inter-sub-band transition energies are shown for single and double cell Ga₂O₃/Al₂O₃.

The results presented above show that a multidimensional surface can be created for band structure characteristics as a function of composition (x, y) and thickness of each (IIIx, Aly)Oz layer, III being a Group 3 element different from Al, in the superlattice. Those results can be used to select, composition (x, y) and thickness of each layer in order to provide a desired (preselected) energy band structure.

Other approaches for selecting composition (x, y) and thickness of each layer in order to provide a desired (preselected) energy band structure are also within the scope of these teachings. For example, the selecting of the composition (x, y) and thickness of each layer that provide a desired (preselected) energy band structure can be cast as an inverse problem (See, for example, Albert Tarantola, Inverse Problem Theory, SIAM, available at C.TARANTOLABOOK.DVI (jpgp.fr)) or as a machine Learning Problem (see, for example, Zhe Shi et al., Deep elastic strain engineering of bandgap through machine learning, Proceedings of the National Academy of Sciences (PNAS), Vol. 116. No. 10, pp. 4117-4122, 2019).

For the purposes of describing and defining the present teachings, it is noted that the term “substantially” is utilized herein to represent the inherent degree of uncertainty that may be attributed to any quantitative comparison, value, measurement, or other representation. The term “substantially” is also utilized herein to represent the degree by which a quantitative representation may vary from a stated reference without resulting in a change in the basic function of the subject matter at issue.

Although the invention has been described with respect to various embodiments, it should be realized these teachings are also capable of a wide variety of further and other embodiments within the spirit and scope of the appended claims.

What is claimed is:

1. A device comprising:
a base structure; and
a superlattice structure, disposed on the base structure, comprising a plurality of (IIIx, Aly)Oz layers, III being a Group 3 element different from Al; wherein a composition (x, y) and thickness of each layer is selected to provide a preselected energy band structure.

2. The device of claim 1 wherein a Group 3 element percentage (x) and an Al percentage (y) are selected such that, for every two layers, a second layer acts as a barrier layer for conduction band electrons.

3. The device of claim 1 wherein a Group 3 element percentage (x) and an Al percentage (y), for each layer, and thickness of each layer from the plurality of (IIIx, Aly)Oz layers are selected such that, for every two layers, band energy levels and miniband energy levels are formed; wherein frequency ranges of operation are determined.

4. The device of claim 1 wherein the Group 3 element is Gallium.

5. The device of claim 3 further comprising a top structure disposed on the superlattice structure.

6. The device of claim 5 wherein at least one of the base structure and the top structure injects carriers into the superlattice structure and wherein the base structure and the top structure act as a resonator; the device acting as a quantum cascade laser.

7. The device of claim 6 wherein radiation is emitted at a wavelength between 1.0 μm and 2.0 μm.

8. The device of claim 6 wherein the Group 3 element is Gallium.

9. The device of claim 6 wherein radiation is emitted at a wavelength between 400 nm and 600 nm.

10. The device of claim 6 wherein radiation is emitted at a wavelength between 400 nm and 2.5 μm.

11. The device of claim 6 wherein radiation is emitted at a wavelength between 400 nm and 10.0 μm.

12. The device of claim 6 wherein the quantum cascade laser acts as a frequency comb.

13. The device of claim 5 wherein at least one of the base structure and the top structure injects carriers into the superlattice structure; and wherein the band energy levels and miniband energy levels are selected such that the device acts as a detector that detects radiation in two frequency ranges.

14. The device of claim 13 further comprising a first electrically conducting contact disposed over at least a portion of the top structure; and a second electrically conducting contact disposed over at least a portion of the base structure.

15. The device of claim 14 wherein at least one of the first electrically conducting contact or the top structure is substantially transparent over a range of frequencies.

16. The device of claim 14 wherein at least one of the second electrically conducting contact or the base structure is substantially transparent over a range of frequencies.

17. The device of claim 13 wherein the Group 3 element is Gallium.

18. The device of claim 13 wherein the frequency ranges are one frequency range in the IR and one frequency range in the UV.

19. The device of claim 1 wherein the superlattice structure is disposed as a ring; the device further comprising;
a top structure disposed on the superlattice structure; the superlattice structure forming a ring resonator; the superlattice structure exhibiting a nonlinearity selected such that the ring resonator produce para metrically generated light; and
a waveguide optically coupled to the ring resonator, the waveguide being arranged for in-coupling an input laser light into the micro-resonator and out-coupling the parametrically generated light out of the ring resonator;
wherein the device acts as a frequency comb.

20. The device of claim 1 wherein the superlattice structure is disposed as a fin structure;
the device further comprising;
an electrically conductive source structure disposed over one end of the superlattice structure;
an electrically conductive drain structure disposed over an opposite end of the superlattice structure; and
an electrically conductive gate structure disposed between the electrically conductive source structure and the electrically conductive drain structure and over the fin structure;
the preselected energy band structure being such that the device operates as a transistor.

21. The device of claim 20 further comprising;
at least one other superlattice structure disposed as another fin structure;
said at least one other superlattice structure disposed parallel to said superlattice structure; said at one other superlattice structure extending from the electrically conductive drain structure to the electrically conductive source structure;
the electrically conductive drain structure disposed over one end of said at least one other superlattice structure;
the electrically conductive source structure disposed over another end of said at least one other superlattice structure; and
the electrically conductive gate structure also disposed over said at least one other superlattice structure.
